(19) United States
(12) Patent Application Publication
(10) Pub. No.: US 2014/0015607 A1
(43) Pub. Date: Jan. 16, 2014

(54) LOW NOISE AMPLIFIERS FOR MULTIPLE RADIO STANDARDS

(71) Applicants: Qiang Li, Irvine, CA (US); Si-Ning Zhou, Irvine, CA (US)

(72) Inventors: Qiang Li, Irvine, CA (US); Si-Ning Zhou, Irvine, CA (US)

(73) Assignee: MStar Semiconductor, Inc., Hsinchu County (TW)

(21) Appl. No.: 13/545,106

(22) Filed: Jul. 10, 2012

(51) Int. Cl. H03F 3/45

(52) U.S. Cl. 330/254

(57) ABSTRACT

Low noise amplifiers and related control methods for multiple radio standards are disclosed. An exemplary low noise amplifier comprises input ports, an output port, amplifier stages, and a degeneration inductor. Each amplifier has a gain stage and a buffer stage connected in series. The buffer stage selectively channels an output of the gain stage to the output port or a power supply. The degeneration inductor is commonly connected to the gain stage in each of the amplifier stages.

### BACKGROUND

The present disclosure relates generally to the design and implementation of radio frequency (RF) receivers, and more specifically, to the design and implementation of low-noise amplifiers (LNAs) for multiple radio standards.

Single integrated circuit chips required to support multiple radio standards tend to be an intuitive simple combination of multiple circuit modules in the IC, with each module accommodates only a single radio standard. Frequency bands allocated for Enhanced Data Rates for GSM (EDGE) and General Packet Radio Services (GPRS) are 850 MHz, 900 MHz, 1.8 GHz and 1.9 GHz, for example, and conventional chips for EDGE and GPRS have been designed using three or four independent Low-Noise Amplifiers (LNAs) cascading with the same number of mixers whose outputs are merged together to feed a single baseband circuit. This kind of approaches has several disadvantages. A costly semiconductor area is required, for instance, because each of LNAs and mixers needs at least one inductive device, which is huge in size. Furthermore, for merging outputs from different mixers, long-distance routings crossing over a large semiconductor area are required, but it is hard for such a routing to achieve low signal loss, low parasitic resistance, and low parasitic capacitance.

In view of the foregoing, it is highly desirable and advantageous to providing a system and method that employs fewer LNAs and/or mixers on a single chip than that currently employed using known techniques while supporting multiple radio standards.

### SUMMARY

An exemplary low noise amplifier is disclosed in the specification, comprising a plurality of input ports, an output port, a plurality of amplifier stages, and a degeneration inductor. Each amplifier has a gain stage and a buffer stage connected in series between one of the input ports and the output port. The buffer stage selectively channels an output of the gain stage to the output port or a power supply. The degeneration inductor is commonly connected to the gain stage in each of the amplifier stages.

An exemplary method for operating a low-noise amplifier is also disclosed. The low-noise amplifier comprises a plurality of input ports, an output port, and a plurality of amplifier stages, each comprising a gain stage coupled between one of the input ports and the output port. A first amplifier stage among the amplifier stages is disabled by biasing the gain stage of the first amplifier stage to an off state and channeling an output current from the gain stage of the first amplifier stage to a power supply. A second amplifier stage among the amplifier stages is enabled by biasing the gain stage of the second amplifier stage to an on state and channeling an output current from the gain stage of the second amplifier stage to the output port.

### BRIEF DESCRIPTION OF THE DRAWINGS

The invention can be more fully understood by the subsequent detailed description and examples with references made to the accompanying drawings, wherein:

FIG. 1 depicts a multi-band RF receiver according to an embodiment of the invention;

FIG. 2 depicts the LNA shown in FIG. 1; and

FIG. 3 shows some resulted signal paths in the LNA of FIG. 2 when the amplifier stage 26₂ is enabled.

### DETAILED DESCRIPTION

It is to be understood that the techniques of the present invention are not limited to the methods and apparatuses shown and described herein. Rather, alternative methods and apparatuses within the scope of the invention will become apparent to those skilled in the art given the teachings therein.

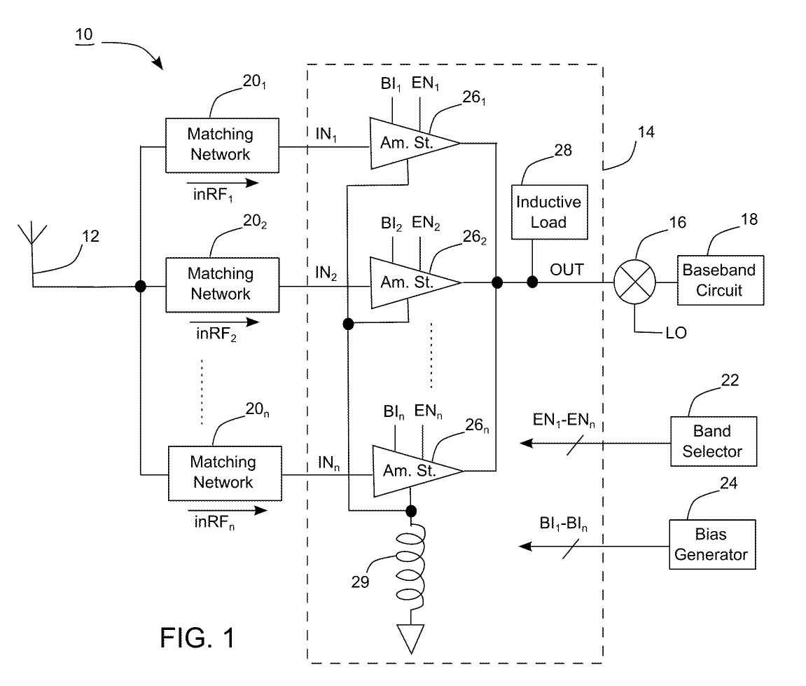

FIG. 1 depicts a multi-band RF receiver 10 according to an embodiment of the invention. The RF receiver 10 includes an antenna 12, several impedance matching networks 20₁-20ₙ, a low-noise amplifier (LNA) 14, a mixer 16, a baseband circuit 18, a band selector 22, and a bias generator 24, where n is an integer larger than 1.

The antenna 12 receives inbound RF signals denoted as inRFi in FIG. 1, which might be carried in different RF bands. Each of the impedance matching network 20ᵢ, where i=1, 2, . . . , n, provides impedance matching for inbound RF signals in one RF band. Accordingly, inbound RF signals inRFᵢ in one frequency band go through a corresponding impedance matching network 20ᵢ, while being rejected by other impedance matching networks. The LNA 14 has several amplifier stages 26₁-26ₙ. Each of the amplifier stage 26ᵢ, if enabled, amplifies corresponding inbound RF signals inRFᵢ, filtered and matched by a corresponding impedance matching network 20ᵢ, and generates a corresponding result in a common output port OUT to drive an inductive load 28. As the impedance matching networks 20₁-20ₙ correspond to respective RF bands for communication, so do the amplifier stages 26₁-26ₙ.

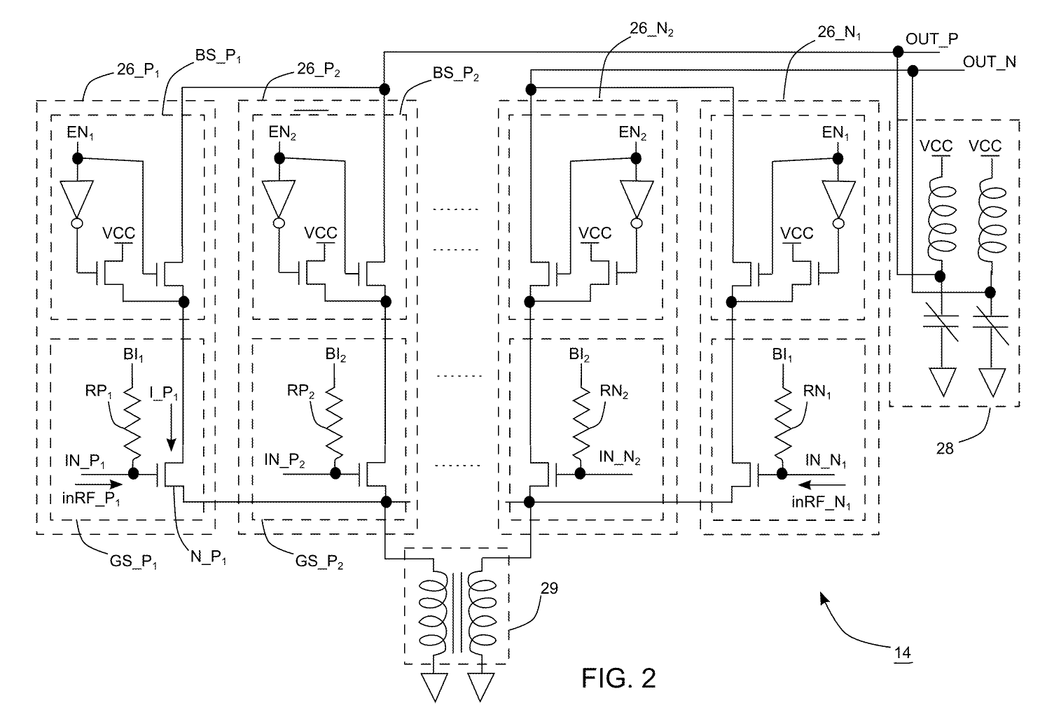

The amplifier stages 26₁-26ₙ share a common degeneration inductor 29 as shown in FIG. 2, which provides a real part of the input impedance to input ports IN₁-INₙ of the entire amplifier stages 26₁-26ₙ. Referring back to FIG. 1, the mixer 16, coupled to the LNA 14, down-converts the signal at the output port OUT of the LNA 14 by mixing signal at output with local oscillation signals LO. The mixer 16 might include a pair of mixers if it is required to receive a pair of differential signals. The mixer 16 accordingly provides baseband signals to the baseband circuit 18 for further signal processing, such as analog-to-digital conversion and demodulation. The band selector 22, based upon an active RF band to be used for receiving RF signals, provides one among the corresponding control signals EN₁-ENₙ to enable corresponding one of the amplifier stages 26₁-26ₙ, meanwhile the other amplifier stages are disabled. Similarly based upon the active RF band, the bias generator 24 provides corresponding bias voltages BI₁-BIₙ to the amplifier stages 26₁-26ₙ, respectively. Except for the bias voltage for an enabled amplifier stage, the remaining bias voltages eliminate the gains of the disabled amplifier stages.

FIG. 2 depicts detail structure of the LNA 14 shown in FIG. 1. The LNA 14 in FIG. 2 has amplifier stages 26₁-26, each of the amplifier stages 26ᵢ being a differential amplifier, having two differential input ports (IN_Pᵢ and IN_Nᵢ) for receiving balanced inbound RF signals inRF_Pᵢ and inRF_Nᵢ, and sharing two common differential output ports (OUT_P and OUT_N) coupled to the inductive load 28, which is further coupled to a power supply VCC. The inductive load 28 includes two inductors and two tunable capacitors, whose resonant frequency is tunable for output impedance matching. Amplifier stage 26₁, for instance, is a differential amplifier with portions 26_P₁ and 26_N₁ sharing the common degeneration inductor 29, which is implemented by two inductors inductively-coupled to each other in FIG. 2. All amplifier stages 26₁-26ₙ are of the same in view of circuitry architecture, such that only the non-inverted portion 26_P₁ of the amplifier stage 26₁ is detailed and the remaining non-inverted portions of the amplifier stages 26₂-26ₙ in FIG. 2 are self-explanatory based on the explanation of the non-inverted portion 26_P₁.

The non-inverted portion 26_P₁ has a gain stage GS_P₁ and a buffer stage BS_P₁ connected in series between the input port IN_P₁ and the output port OUT_P. The gain stage GS_P₁ includes a common source amplifier, where the source of NMOS N_P₁ is connected to a degeneration inductor 29, and the gate of NMOS N_P₁ is coupled to the bias voltage BI₁ through resistor RP₁. The bias voltages BI₁ provided from the bias generator 24 (shown in FIG. 1) substantially determines the transconductance of NMOS N_P₁, whose gate functions as the input port IN_P₁ to receive the inbound RF signals inRF_P₁ from the impedance matching networks 20₁ (in FIG. 1) to generate output current I_P₁. The buffer stage BS_P₁ includes a common gate amplifier, for channeling the output current I_P₁ to the output port OUT_P based on the control signal EN₁.

When the amplifier stage 26₁ is enabled, the band selector 22 asserts the control signal EN₁ and the bias generator 24 keeps the bias voltages BI₁ at a high level above the threshold voltage of the NMOS N_Pₗ. Thus, the gain stage GS_P₁ is now operating in an ON state, and the output current I_P₁ reflects the amplitude of the inbound RF signals inRF_Pᵢ at the gate of the NMOS N_Pₗ. Because the NMOS in the common gate amplifier is conducted, the output current I_P₁ is then channeled to the output port OUT_P. On the contrary, when the amplifier stage 26₁ is disabled, the band selector 22 disasserts the control signal EN₁ and the bias generator 24 turns the bias voltages BI₁ to be a low level under the threshold voltage of the NMOS N_P₁. For example, the bias voltages BI₁ could be zero. The gain stage GS_P₁ is now operating in an OFF state as the NMOS N_P₁ is turned off. As a result, the common gate amplifier is turned off and it no longer provides a channel to the output node OUT_P. Also, there is no induced output current I_P₁ because the NMOS N_P₁ is turned off, leaving the output port OUT_P driven by another amplifier stage.

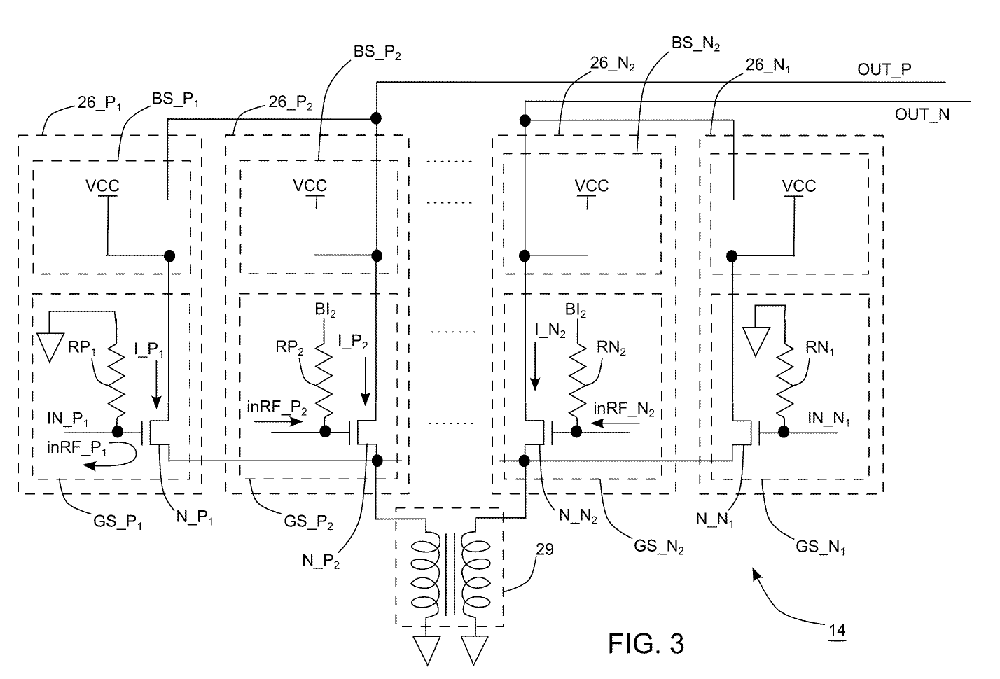

FIG. 3 depicts signal paths in the LNA 14 of FIG. 2 when the amplifier stage 26₂ is enabled. If the inbound RF signals inRF₂, consisting of balanced RF signals inRF_P₂ and inRF_N₂, are to be used for communication, all the amplifier stages other than amplifier stage 26₂ are disabled because control signals EN₁, EN₃-ENₙ are off and bias voltages BI₁, BI₃-BIₙ are at ground level. Any interfering RF signals that go through impedance matching networks 20₁, 20₃-20ₙ, other than impedance matching networks 20₂, are rejected by the NMOSs of which gate is grounded in the gain stages, or have no influence on the output ports OUT_P and OUT_N, which are currently disconnected from the gain stages GS_P₁, GS_N₁, GS_P₃-GS_Pₙ, and GS_N₃-GS_Nₙ. The enabled amplifier stage 26₂, amplifies the inbound RF signals inRF₂ as the bias voltages BI₂ is higher than the threshold voltages of the NMOSs N_N₂ and N_P₂. Furthermore, the control signal EN₂ allows the buffer stages BS_P₂ and BS_N₂ to provide electrical connections from the drain of the NMOS N_P₂ to the output port OUT_P and from the drain of the NMOS N_N₂ to the output port OUT_N. The output currents I_P₂ and I_N₂ are accordingly channeled to the output ports OUT_P and OUT_N, respectively.

If the inbound RF signals inRF₁, for instance, are to be amplified, all but the amplifier stage 26₁ are disabled. The control signal EN₁ is asserted while the control signals EN₂-ENₙ are off. The bias voltage BI₁ becomes higher than an NMOS threshold voltage, and the bias voltages BI₂-BIₙ become zero. The present operation of the LNA 14 is analogous to the description in the previous paragraph and is omitted herein for purposes of brevity.

An advantage of the present invention is the lower semiconductor cost of the single integrated circuit chip embodying the multi-band RF receiver 10 in FIG. 1. Unlike the techniques taught in the prior art which needs individual mixers for different LNAs, only one mixer 16 is needed, as shown in FIG. 1. Furthermore, instead of employing several source degeneration inductors in different amplifier stages, only one source degeneration inductor 29, commonly shared by amplifier stages 26₁-26ₙ is needed. The required number of inductors as well as the semiconductor cost is thus reduced. Nevertheless, the present invention is not limited to FIG. 1. Some other embodiments covered by the invention might employ more than one mixer and source degeneration inductor.

Please also note that the LNA 14 is capable of avoiding impedance node noise pickup. High impedance nodes are notorious for its higher thermal noise and the tendency of capacitive and inductive noise pickup. The drains of NMOSs in any disabled amplifier stages of the LNA 14 are connected to the power supply VCC and are therefore not high impedance nodes. Thus, noise pickup can be avoided. Even though each disabled buffer stage in FIG. 2 channels an output current to the power supply VCC, a disabled buffer stage in another embodiment could channel an output current to another power supply, such as ground, to avoid impedance node noise pickup.

While the invention has been described by way of example and in terms of preferred embodiment, it is to be understood that the invention is not limited thereto. To the contrary, it is intended to cover various modifications and similar arrangements (as would be apparent to those skilled in the art) . Therefore, the scope of the appended claims should be accorded the broadest interpretation so as to encompass all such modifications and similar arrangements.

What is claimed is:

1. A low noise amplifier, comprising:
a plurality of input ports and an output port;
a plurality of amplifier stages, each comprising a gain stage and a buffer stage connected in series, wherein the buffer stage selectively channels an output of the gain stage to the output port or a power supply; and
a degeneration inductor, commonly connected to the gain stages of the plurality of amplifier stages.

2. The low noise amplifier of claim 1, further comprising a bias generator, providing a bias voltage to the gain stage;
wherein, when the buffer stage channels the output of the gain stage to the power supply, the bias voltage substantially eliminates a gain of the gain stage.

3. The low noise amplifier of claim 1, wherein the gain stage comprises a common-source amplifier, and the buffer stage comprises a common-gate amplifier.

4. The low noise amplifier of claim 1, further comprising an inductive load, coupled between the output port and the power supply.

5. The low noise amplifier of claim 1, wherein the gain stage of each of the amplifier stage is coupled to an impedance matching network.

6. The low noise amplifier of claim 1, wherein only one among the amplifier stages is enabled to channel the output of the gain stage of the enabled amplifier stage to the output port.

7. The low noise amplifier of claim 6, further comprising a band selector, for providing a control signal to control the buffer stage.

8. The low noise amplifier of claim 1, wherein the output port is coupled to a mixer for down-conversion.

9. The low noise amplifier of claim 1, wherein each of the amplifier stage corresponds to an individual radio frequency band.

10. The low noise amplifier of claim 1, further comprising an inductive load, coupled between the output port and another power supply.

11. A method for operating a low-noise amplifier comprising a plurality of input ports, an output port, and a plurality of amplifier stages, each comprising a gain stage coupled between one of the input ports and the output port, the method comprising:
disabling a first amplifier stage among the amplifier stages by biasing the gain stage of the first amplifier stage to an off state and channeling an output current from the gain stage of the first
enabling a second amplifier stage among the amplifier stages by biasing the gain stage of the second amplifier stage to an on state and channeling an output current from the gain stage of the second amplifier stage to the output port

12. The method of claim 11, wherein each of the amplifier stage comprises a buffer stage connected between the gain stage and the output port, the method further comprising selectively channeling an output of the gain stage to the output port or a power supply.

13. The method of claim 11, wherein the gain stage of each of the amplifier stage commonly share a degeneration inductor.
